(19) United States
(12) Patent Application Publication
(10) Pub. No.: US 2025/0096046 A1
(43) Pub. Date: Mar. 20, 2025

(54) STRUCTURE FOR TESTING INTERFACIAL ADHESION BETWEEN MOLD COMPOUND AND VERTICAL EDGES OF A SEMICONDUCTOR DIE

(71) Applicant: Micron Technology, Inc., Boise, ID (US)

(72) Inventors: Faxing CHE, Singapore (SG); Chong Leong GAN, Taichung (TW); Yeow Chon ONG, Toa Payoh (SG); Hong Wan NG, Singapore (SG)

(21) Appl. No.: 18/783,279

(22) Filed: Jul. 24, 2024

Related U.S. Application Data
(60) Provisional application No. 63/582,652, filed on Sep. 14, 2023.

(51) Int. Cl. H01L 21/66; H01L 23/00; H01L 23/31; H01L 25/065

(52) U.S. Cl. CPC H01L 22/30; H01L 23/3114; H01L 23/562; H01L 25/0657; H01L 2225/06596

(57) ABSTRACT

Implementations described herein relate to techniques and apparatuses related to a structure that may be used for characterizing properties related to an interfacial adhesion strength between an epoxy mold compound and a vertical edge of a semiconductor die included in a semiconductor die package. The techniques and apparatuses may be used to provide a more comprehensive understanding of interfacial adhesion strengths within the semiconductor die package relative to techniques available in semiconductor industry standards.

### CROSS-REFERENCE TO RELATED APPLICATION

This patent application claims priority to U.S. Provisional Patent Application No. 63/582,652, filed on Sep. 14, 2023, entitled “STRUCTURE FOR TESTING INTERFACIAL ADHESION BETWEEN MOLD COMPOUND AND VERTICAL EDGES OF A SEMICONDUCTOR DIE,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to a structure used for testing interfacial adhesion between a mold compound and vertical edges of a semiconductor die.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., a circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram illustrating an example implementation of a test vehicle for testing one or more properties related to an interfacial adhesion strength associated with a semiconductor die package described herein.

FIGS. 4A-4E are diagrams of an example implementation for forming a test vehicle to test one or more properties related to an interfacial adhesion strength related to a semiconductor die package described herein.

FIG. 5 is a diagram illustrating example implementations of test vehicles for testing one or more properties related to an interfacial adhesion strength between an epoxy mold compound and a vertical edge of a die described herein.

FIGS. 6A-6F are diagrams of an example implementation for forming an example test vehicle for testing one or more properties related to an interfacial adhesion strength between an epoxy mold compound and a vertical edge of a die described herein.

FIGS. 7A-7D are diagrams of example implementations of an interfacial adhesion strength testing tool described herein.

FIG. 8 is a diagram of example components of a device that characterizes properties related to an interfacial adhesion strength between an epoxy mold compound and vertical edges of a die described herein.

FIG. 9 is a flowchart of an example method associated with testing properties related to an interfacial adhesion strength between an epoxy mold compound and vertical edges of a die.

FIG. 10 is a flowchart of an example method of forming an integrated assembly having an interfacial adhesion strength testing structure.

### DETAILED DESCRIPTION

A semiconductor die package may include one or more semiconductor dies. In a case of the semiconductor die package including multiple semiconductor dies, two or more of the multiple semiconductor dies may be in a stacked arrangement to reduce a footprint of the semiconductor die package. The semiconductor die package may also include a casing that encapsulates one or more of the semiconductor dies to provide mechanical protection, environmental protection (from moisture and contaminants), and electrical insulation. In some implementations, the casing includes an epoxy mold compound material.

Delamination of interfaces between the epoxy mold compound material and semiconductor dies included in the semiconductor die package may have a significant effect on a quality and/or a reliability of the semiconductor die package. Qualification of the semiconductor die package for field use may include interfacial adhesion tests to characterize properties related to an interfacial adhesion strength between the epoxy mold compound and the semiconductor dies within the semiconductor die package. For example, JEDEC (Joint Electron Device Engineering Council) publication JEP167A describes techniques related to a characterization of interfacial adhesion in semiconductor die packages.

Techniques described in JEP167A include a “button shear” technique to characterize properties related to the interfacial adhesion strength for interface regions between a horizontal surface of a semiconductor die and the epoxy mold compound that is over the horizontal surface. However, JEP167A fails to describe techniques to characterize properties related to the interfacial adhesion strength for interface regions between a vertical edge of the semiconductor die and the epoxy mold compound that is adjacent to the vertical edge. In a case where the semiconductor die package includes multiple semiconductor dies in the stacked arrangement, an inaccurate characterization and/or an insufficient understanding of the interfacial adhesion strength between vertical edges of the multiple semiconductor dies and the epoxy mold compound may result in a premature qualification of the semiconductor die package for field use. Such a premature qualification may result in a rate of field failures and/or a rate of field returns that is unacceptable for a market consuming the semiconductor die package.

Some implementations described herein provide techniques and apparatuses related to a structure that may be used for characterizing properties related to an interfacial adhesion strength between an epoxy mold compound and a vertical edge of a semiconductor die included in a semiconductor die package. The techniques and apparatuses may be used to provide a more comprehensive understanding of interfacial adhesion strengths within the semiconductor die package relative to techniques that may be limited to button shear techniques as described in JEP167A. For example, and in contrast to the techniques currently described in JEP167A, the implementations described herein enable characterizing properties related to the interfacial adhesion strength between the vertical edge of the semiconductor die and the epoxy mold compound.

In this way, a thoroughness of a qualification of the semiconductor die package for field use may be improved, to reduce a rate of field failures and/or a rate of field returns for a market consuming the semiconductor die package. By reducing the rate of field failures and/or the rate of field returns, an amount of resources required to support the market consuming the semiconductor die package (e.g., semiconductor manufacturing tools, labor, raw materials, and/or computing resources) may be reduced.

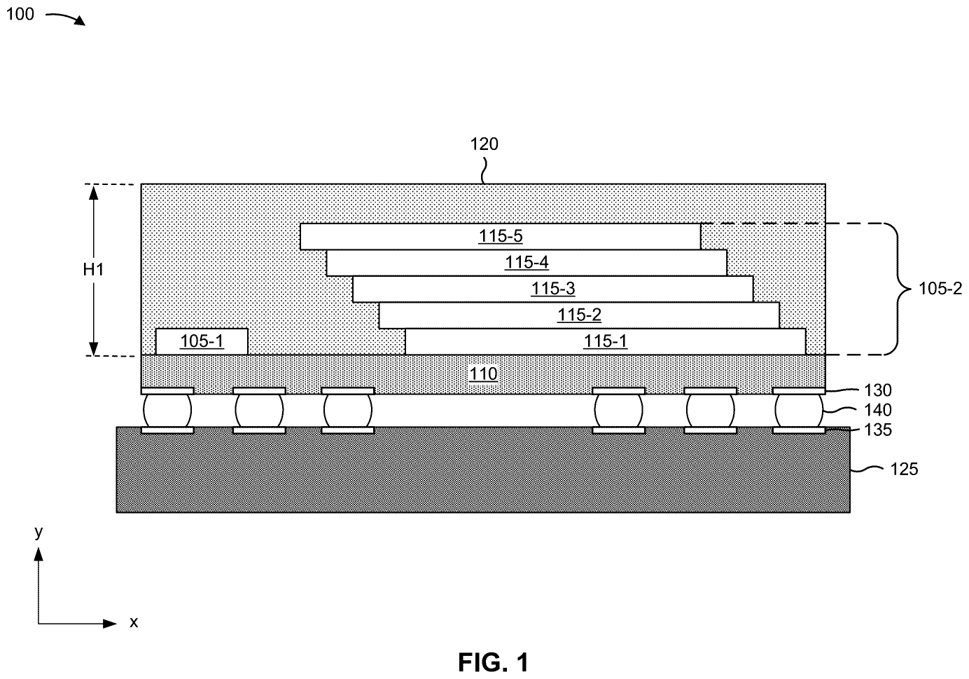

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five dies 115.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100. In some implementations, a height H1 of the casing 120 may varies with a quantity of dies 115 that may be included in the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

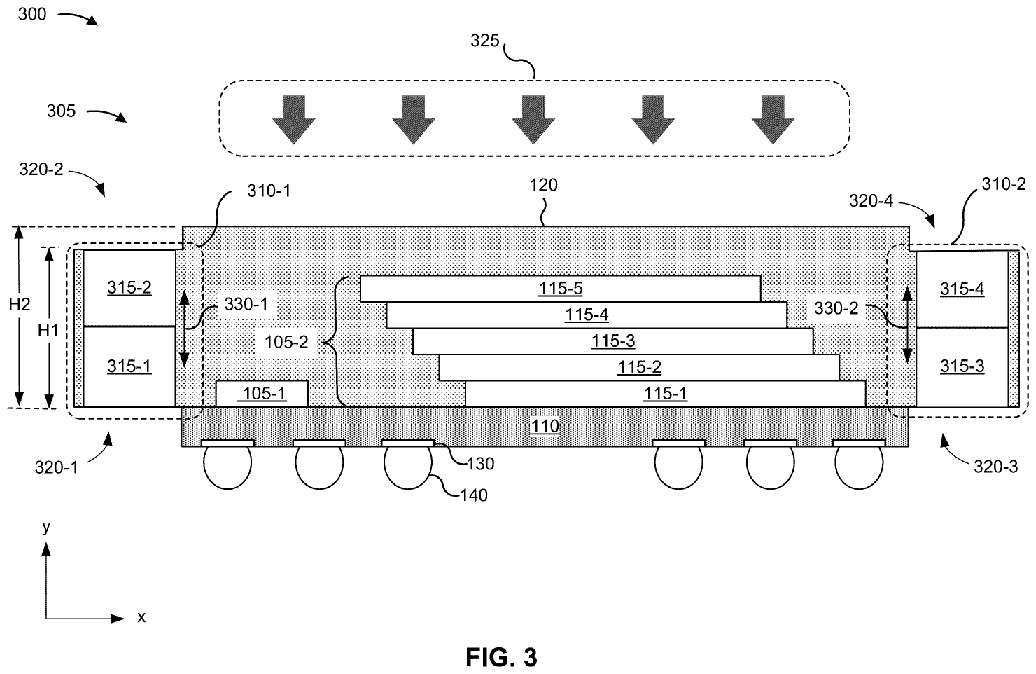

As described in greater detail in connection with FIGS. 3-10, an interfacial adhesion testing structure may be used for characterizing properties related to an interfacial adhesion strength between the epoxy mold compound of the casing 120 and vertical edges of the dies 115. Techniques using the interfacial adhesion testing structure may be used to provide a more comprehensive understanding of interfacial adhesion strengths within the apparatus 100 relative to techniques described in semiconductor industry standards.

In this way, a thoroughness of a qualification of the apparatus 100 for field use may be improved, to reduce a rate of field failures and/or a rate of field returns for a market consuming the apparatus 100. By reducing the rate of field failures and/or the rate of field returns, an amount of resources required to support the market consuming the apparatus 100 (e.g., semiconductor manufacturing tools, labor, raw materials, and/or computing resources) may be reduced.

As indicated above, FIG. 1 is provided as an example. Other examples may differ from what is described with regard to FIG. 1.

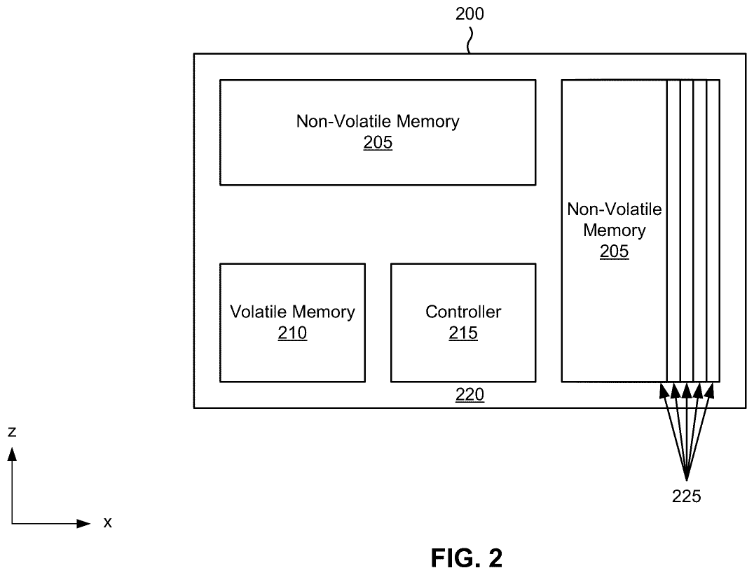

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

In some implementations, the memory device 200 includes one or more semiconductor die packages (e.g., one or more of the apparatus 100 described in connection with FIG. 1). Using techniques described in connection with FIGS. 3-10 and elsewhere herein, a comprehensive understanding of interfacial adhesion strengths within the one or more semiconductor die packages may reduce a rate of field failures of the memory device 200, to satisfy target quality and reliability thresholds related to a market consuming the memory device.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIG. 3 is a diagram 300 illustrating an example implementation of a test vehicle 305 for testing one or more properties related to an interfacial adhesion strength associated with a semiconductor die package described herein. The test vehicle 305 may replicate one or more aspects of a semiconductor die package (e.g., the apparatus 100 of FIG. 1).

The test vehicle 305 includes an interfacial adhesion testing structure 310-1 that extends laterally beyond vertical edges of the dies 115. In some implementations, the interfacial adhesion testing structure 310-1 includes a same epoxy mold compound as the casing 120. Further, in some implementations, the interfacial adhesion testing structure 310-1 includes reinforcement structures 315-1 and 315-2, where the reinforcement structures 315-1 and 315-2 are embedded in the epoxy mold compound. The reinforcement structures 315-1 and 315-2 may be stacked in a vertical arrangement. Additionally, or alternatively, the reinforcement structures 315-1 and 315-2 may be approximately planar and rectangular structures that include a silicon material, a metal material, a ceramic material, a composite material, or another suitable material, among other examples.

In some implementations, the reinforcement structure 315-1 and/or the reinforcement structure 315-2 may have a thickness that is different than a thickness of a die of the integrated circuit 105-2 (e.g., different than a thickness of one or more of the dies 115). Additionally, or alternatively, the reinforcement structure 315-1 and/or the reinforcement structure 315-2 may have a thickness that is a same approximate thickness as a die of the integrated circuit 105-2 (e.g., a same approximate thickness as one or more of the dies 115).

Additionally, or alternatively, the test vehicle 305 includes the interfacial adhesion testing structure 310-2 that extends laterally beyond vertical edges of the dies 115. In some implementations, the interfacial adhesion testing structure 310-2 includes a same epoxy mold compound as the casing 120. Further, and in some implementations, the interfacial adhesion testing structure 310-2 includes reinforcement structures 315-3 and 315-4, where the reinforcement structures 315-3 and 315-4 are embedded in the epoxy mold compound. The reinforcement structures 315-3 and 315-4 may be approximately planar and rectangular structures that include a silicon material, a metal material, a ceramic material, a composite material, or another suitable material, among other examples.

In some implementations, the reinforcement structure 315-3 and/or the reinforcement structure 315-4 may have a thickness that is different than a thickness of a die of the integrated circuit 105-2 (e.g., different than a thickness of one or more of the dies 115). Additionally, or alternatively, the reinforcement structure 315-3 and/or the reinforcement structure 315-4 may have a thickness that is a same approximate thickness as a die of the integrated circuit 105-2 (e.g., a same approximate thickness as one or more of the dies 115).

In some implementations, and as shown in FIG. 3, the test vehicle 305 includes a recess 320-1 that is below the reinforcement structures 315-1 and 315-2. Additionally, or alternatively, the test vehicle 305 includes a recess 320-2 that is above the reinforcement structures 315-1 and 315-2. Additionally, or alternatively, the test vehicle 305 includes a recess 320-3 that is below the reinforcement structures 315-3 and 315-4. Additionally, or alternatively, the test vehicle 305 includes a recess 320-4 that is above the reinforcement structures 315-3 and 315-4.

The test vehicle 305 may include a thickness H2. Furthermore, and based on the recesses 320-1 through 320-4, the interfacial adhesion testing structures 310-1 and 310-2 may have a thickness H1. The thickness H1, which may replicate a thickness of a semiconductor die package included in a final product (e.g., a semiconductor die package included in the apparatus 100), may be less than H2.

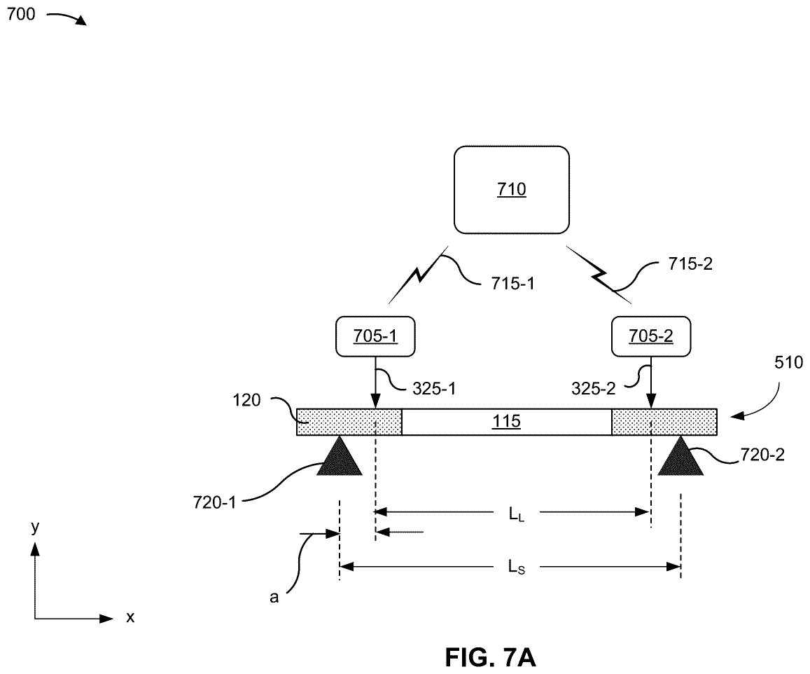

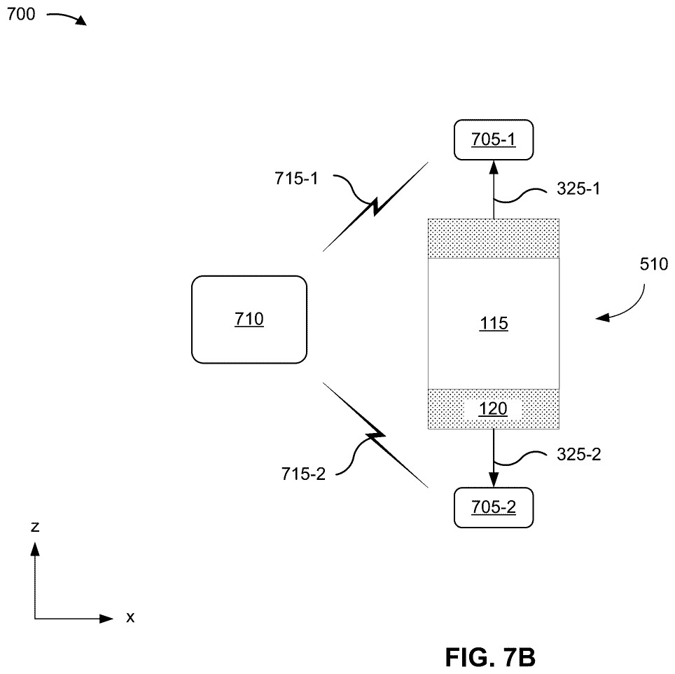

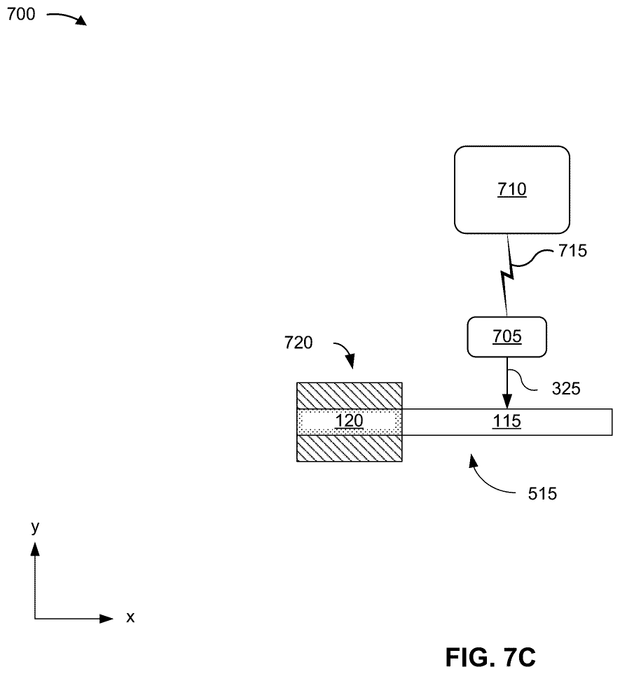

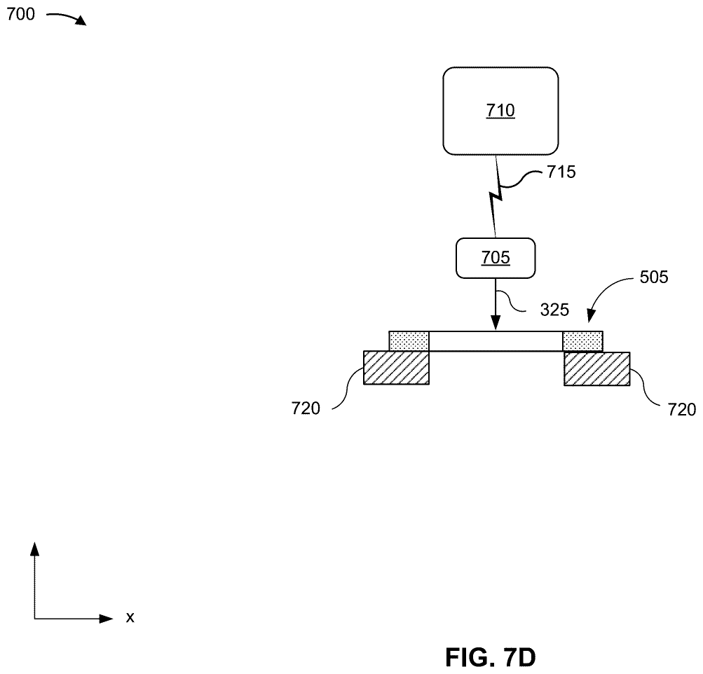

The test vehicle 305 (e.g., the test vehicle 305 including integrated circuits 105-1 and 105-2 (e.g., the dies 115), the substrate 110, the electrical contacts 130, and/or the solder balls 140) may include flexure and/or rigidity properties similar to those of the semiconductor die package included in the final product (e.g., the semiconductor die package included in the apparatus 100). As described in greater detail in connection with FIGS. 7A-7D and as part of qualifying a use of the semiconductor die package (e.g., the semiconductor die package that is replicated by the test vehicle 305) in the final product, a mechanical load 325 may be applied to the test vehicle 305 to determine one more properties related to an interfacial adhesion strength between the epoxy mold compound (e.g., the casing 120) and vertical edges of the dies 115.

As shown and described in connection with FIG. 3, an integrated assembly (e.g., the test vehicle 305) includes a substrate (e.g., the substrate 110); one or more semiconductor dies (e.g., the dies 115) on the substrate; a casing (e.g., the casing 120) having a first thickness (e.g., the thickness H2) over the one or more semiconductor dies and comprising an epoxy mold compound; and an interfacial adhesion testing structure (e.g., the interfacial adhesion testing structure 310-1 and/or the interfacial adhesion testing structure 310-2) extending laterally beyond vertical edges of the one or more semiconductor dies and beyond an edge of the substrate, wherein the interfacial adhesion testing structure comprises the epoxy mold compound, and wherein a second thickness of the interfacial adhesion testing structure (e.g., the thickness H1) is less than the first thickness.

As indicated above, FIG. 3 is provided as an example. Other examples may differ from what is described with regard to FIG. 3.

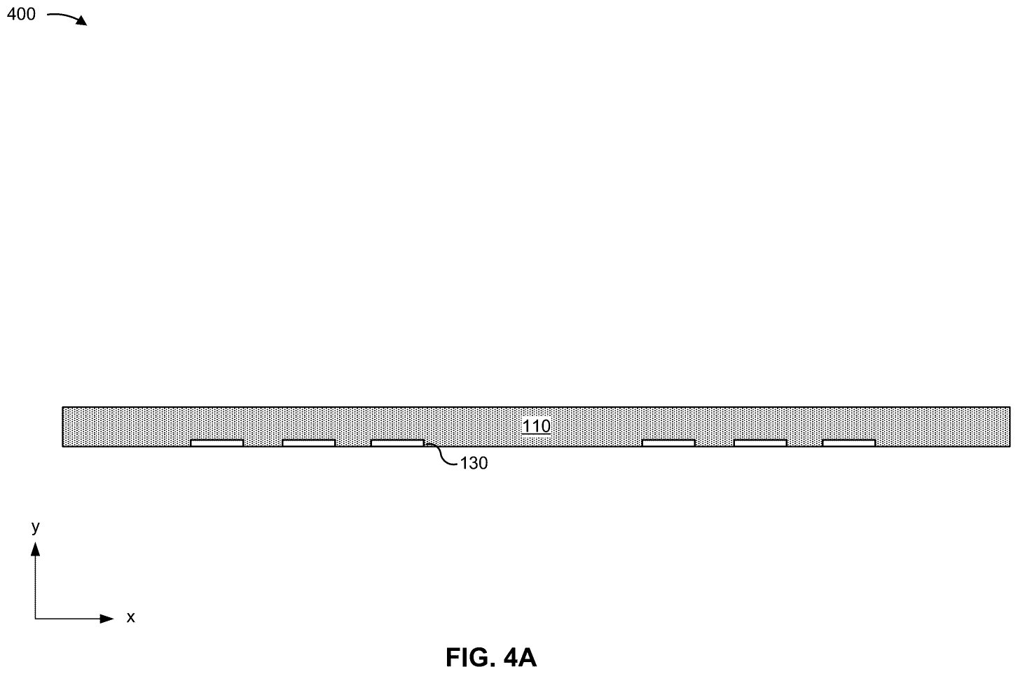

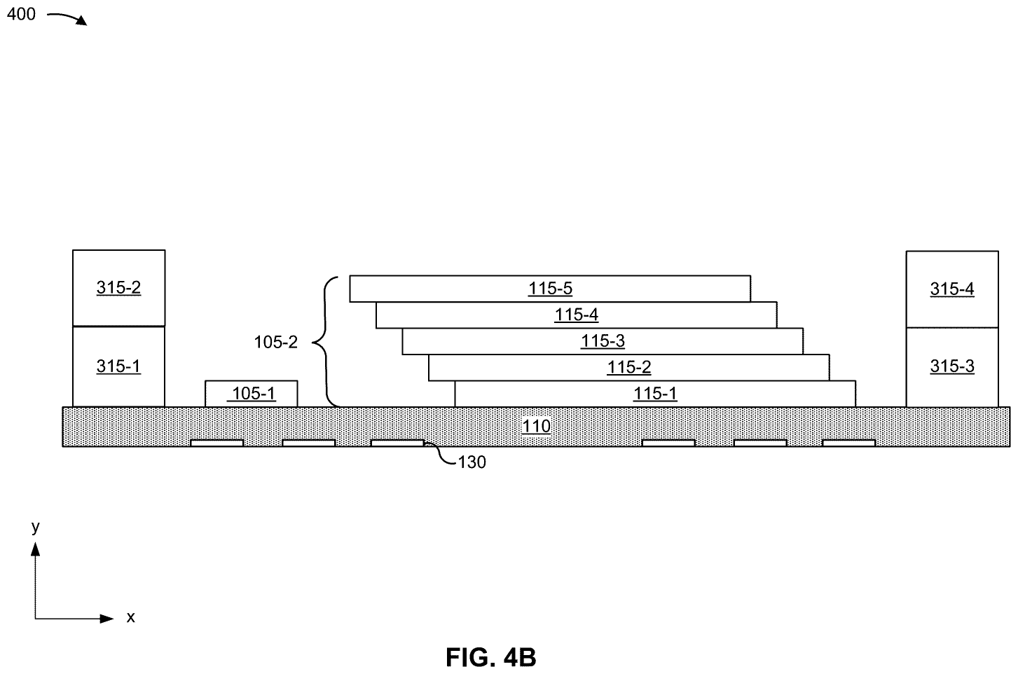

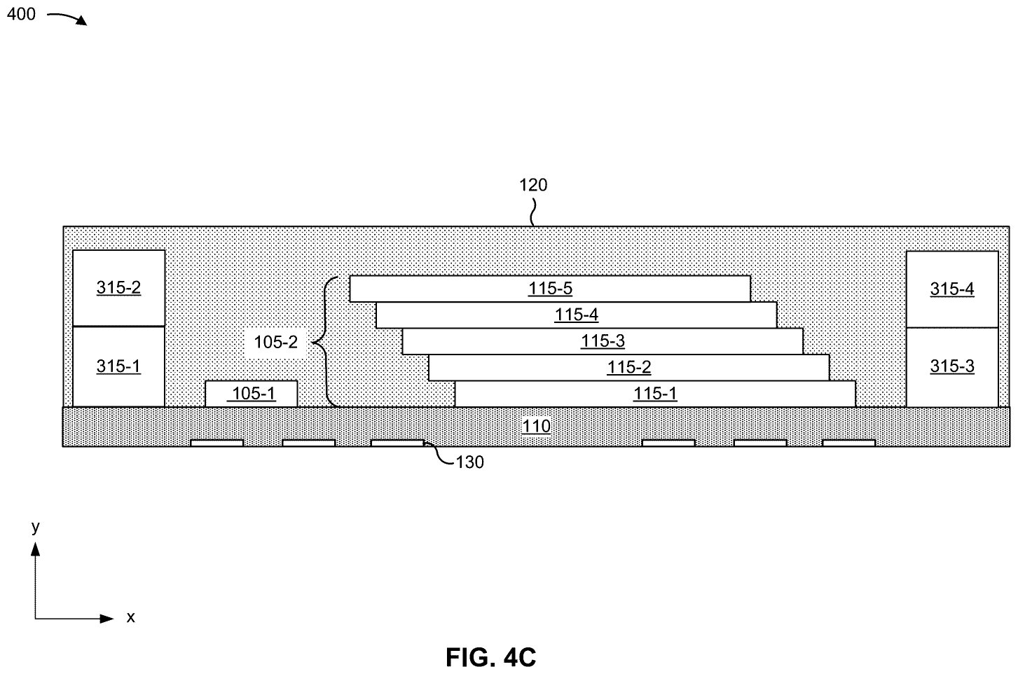

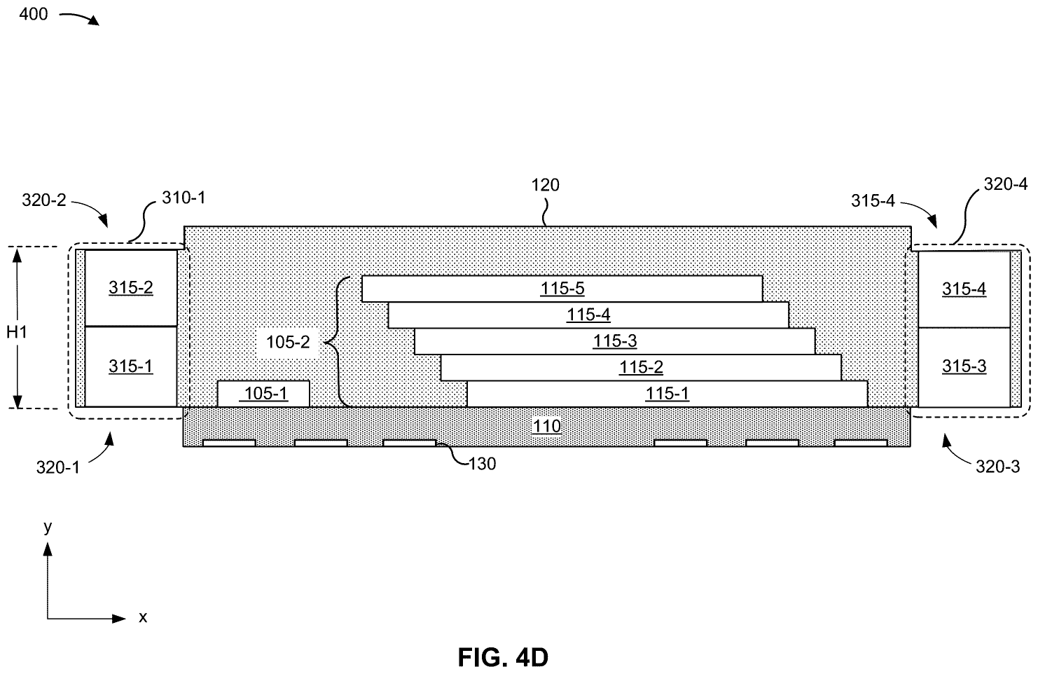

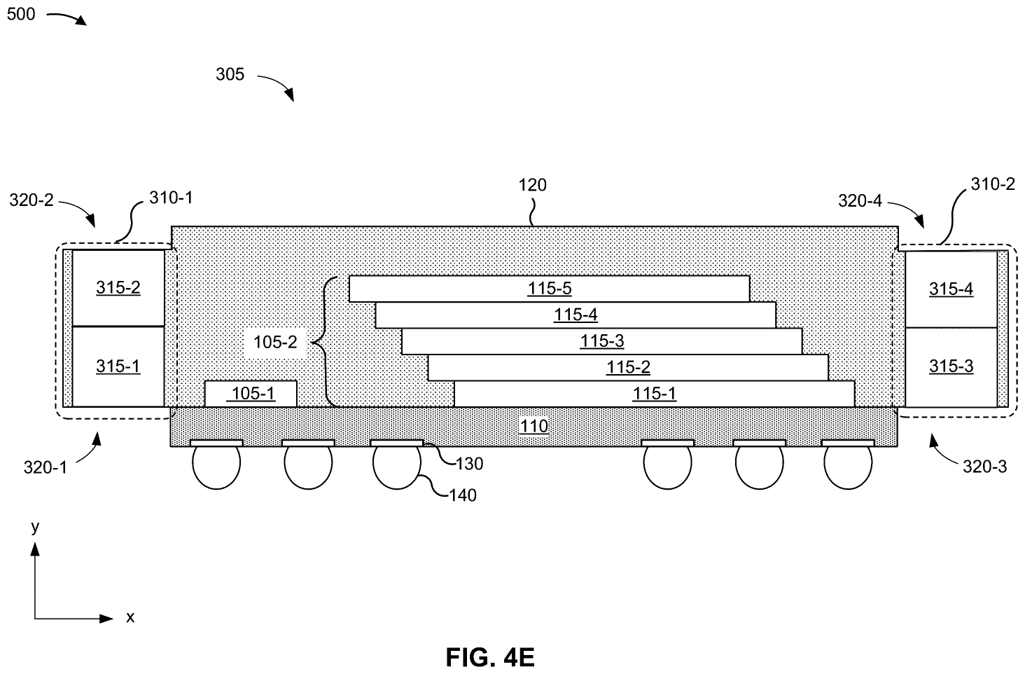

FIGS. 4A-4E are diagrams of an example implementation 400 for forming a test vehicle for testing one or more properties related to an interfacial adhesion strength associated with a semiconductor die package described herein. The implementation 400 may include a series of semiconductor processing operations that may be used to form the test vehicle 305 as described in connection with FIG. 3.

As shown in FIG. 4A, the implementation 400 includes forming the substrate 110 having the electrical contacts 130. As an example, forming the substrate 110 and/or the electrical contacts 130 may include forming a printed circuit board (PCB) using a combination of lamination, plating, silkscreen printing, etching, and/or drilling techniques. Additionally, or alternatively, forming the substrate 110 having the electrical contacts 130 may include forming an interposer using redistribution layer (RDL) formation semiconductor processing operations on a silicon substrate.

Turning to FIG. 4B, the implementation 400 includes forming a stack of the dies 115 on the substrate 110. The implementation 400 further includes forming the reinforcement structures 315-1 and 315-2 on the substrate 110 adjacent to a side of the stack of the dies 115, and the reinforcement structures 315-3 and 315-4 on the substrate 110 adjacent to an opposite side of the stack of the dies 115.

As an example, a die attachment technique incorporating an adhesive and/or tape material may be used to form the stack of the dies 115 and the reinforcement structures 315 on the substrate 110. Additionally, or alternatively and in a case in which one or more of the dies 115 and/or one or more of the reinforcement structures 315 include a bumped interconnect structure, a reflow technique may be used to form the stack of the dies 115 and/or the reinforcement structures 315 on the substrate 110.

Turning to FIG. 4C, the implementation 400 includes forming the casing 120 on and/or over the stack of the dies 115 and the reinforcement structures 315. As an example, forming the casing 120 may include using an injection molding and curing technique that uses an epoxy mold compound to form the casing 120. Additionally, or alternatively and after the casing 120 is formed on and/or over the stack of the dies 115 and the reinforcement structures 315, a laser marking technique may be used to mark a sample identifier (e.g., a sample number, a lot number, or a type of epoxy mold compound, among other examples) on the casing 120.

Turning to FIG. 4D, the implementation 400 includes forming the recess 320-1 below the reinforcement structures 315-1 and 315-2 and the recess 320-3 below the reinforcement structures 315-3 and 315-4. As an example, forming the recess 320-1 may include using a step-cutting technique to remove a portion of the substrate 110 that is below the reinforcement structures 315-1 and 315-2. Additionally, or alternatively, forming the recess 320-3 may include using the step-cutting technique to remove a portion of the substrate 110 that is below the reinforcement structures 315-3 and 315-4.

As further shown in FIG. 4D, the implementation 400 includes forming the recess 320-2 above the reinforcement structures 315-1 and 315-2 and the recess 320-4 below the reinforcement structures 315-3 and 315-4. As an example, forming the recess 320-2 may include using a step-cutting technique to remove a portion of the casing 120 that is above the reinforcement structures 315-1 and 315-2. Additionally, or alternatively, forming the recess 320-4 may include using the step-cutting technique to remove a portion of the substrate 110 that is above the reinforcement structures 315-3 and 315-4.

Forming the recesses 320-1 and 302-2 may render the interfacial adhesion testing structure 310-1. Forming the recesses 320-3 and 320-4 may render the interfacial adhesion testing structure 310-2.

Turning to FIG. 4E, the implementation 400 includes forming the solder balls 140 on the electrical contacts 130. As an example, forming the solder balls 140 may include using solder ball placement and/or reflow techniques to form the solder balls 140.

In some implementations, the implementation 400 includes additional semiconductor processing steps that may pre-condition the test vehicle 305 prior to subsequent interfacial adhesion strength tests. Such semiconductor processing steps may include one or more processing steps related to a temperature and humidity cycling operation, a thermal aging operation, a high-temperature storage operation, a thermal shock operation, or a thermal cycling operation, among other examples.

As described in connection with FIGS. 4A-4E, a series of semiconductor processing operations includes forming a stack of one or more semiconductor dies (e.g., the dies 115) on a substrate (e.g., the substrate 110); forming a reinforcement structure (e.g., the reinforcement structures 315) on the substrate adjacent to the stack of one or more semiconductor dies; forming a casing (e.g., the casing 120) over the stack of one or more semiconductor dies and over the reinforcement structure; removing a portion of the substrate that is below the reinforcement structure; and removing a portion of the casing that is above the reinforcement structure, wherein removing the portion of the casing in combination with removing the portion of the substrate forms an interfacial adhesion testing structure (e.g., the interfacial adhesion testing structure 310-1 and/or the interfacial adhesion testing structure 310-2) that is reinforced and that extends laterally beyond vertical edges of the one or more semiconductor dies.

As indicated above, FIGS. 4A-4E are provided as an example. Other examples may differ from what is described with regard to FIGS. 4A-4E.

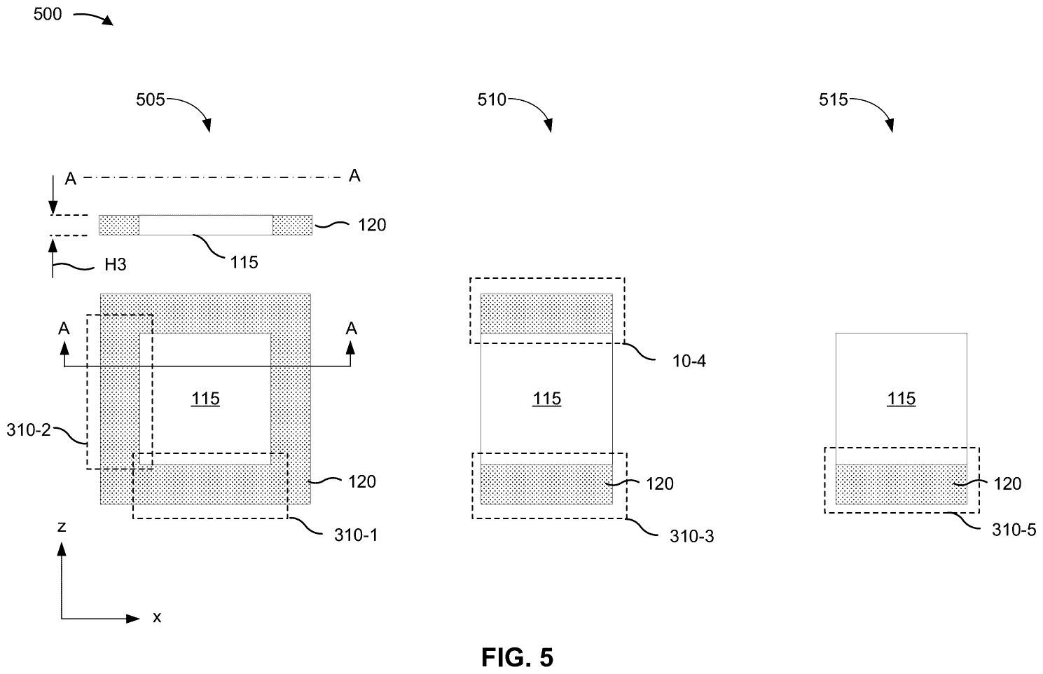

FIG. 5 is a diagram 500 illustrating example implementations of test vehicles 505, 510, and 515 for testing one or more properties related to an interfacial adhesion strength between an epoxy mold compound and a vertical edge of a die described herein. In contrast to the test vehicle 305 described in connection with FIGS. 3 and 4, the test vehicles 505, 510, and 515 include a single die (e.g., the die 115) and the casing 120 (e.g., each of the test vehicles 505, 510, and 515 excludes the reinforcement structure 315 and/or extraneous features that may be included in a semiconductor die package such as the substrate 110, the electrical contacts 130, the solder balls 140, and/or a stack arrangement including the die 115). The test vehicle 505, 510, and/or 515 may isolate one or more aspects of an interfacial region between the casing 120 (e.g., the epoxy mold compound) and the die 115 without influences from such additional structures or features.

As shown in FIG. 5, the test vehicle 505 includes the interfacial adhesion testing structure 310-1 and the interfacial adhesion testing structure 310-2. As part of the test vehicle 505, an edge of the die 115 (e.g., a vertical edge) that is associated with the interfacial adhesion testing structure 310-2 may be approximately orthogonal to another edge of the die 115 (e.g., another vertical edge) that is associated with the interfacial adhesion testing structure 310-1. Further, and as shown in FIG. 5, the edge of the die 115 that is associated with the interfacial adhesion testing structure 310-2 is an adjacent edge that intersects the edge that is associated with the interfacial adhesion testing structure 310-1. Further, and as shown in the section A-A, a thickness H3 of the casing 120 (e.g., the epoxy mold compound) and a thickness of the die 115 may be a same approximate thickness.

As shown in FIG. 5, the test vehicle 510 includes the interfacial adhesion testing structure 310-3 and the interfacial adhesion testing structure 310-4. As part of the test vehicle 510, an edge of the die 115 (e.g., a vertical edge) that is associated with the interfacial adhesion testing structure 310-4 may be an opposite edge that is parallel to another edge (e.g., another vertical edge) that is associated with the interfacial adhesion testing structure 310-3. Additionally, or alternatively and similar to the test vehicle 505, a thickness of the interfacial adhesion testing structure 310-3 and/or 310-4 may be a same thickness as the die 115.

As shown in FIG. 5, the test vehicle 515 includes the interfacial adhesion testing structure 310-5 (e.g., a single interfacial adhesion testing structure). Additionally, or alternatively and similar to the test vehicle 505, a thickness of the interfacial adhesion testing structure 310-5 may be a same thickness as the die 115.

As described in connection with FIG. 5, an integrated assembly (e.g., the test vehicle 505, 510, and/or 515) includes a semiconductor die (e.g., the die 115); and an interfacial adhesion testing structure (e.g., the interfacial adhesion testing structure 310-1, 310-2, 310-3, 310-4, and/or 310-50) extending laterally beyond a vertical edge of the semiconductor die, wherein a thickness (e.g., the thickness H3) of the interfacial adhesion testing structure and a thickness of the semiconductor die are a same approximate thickness.

As indicated above, FIG. 5 is provided as an example. Other examples may differ from what is described with regard to FIG. 5.

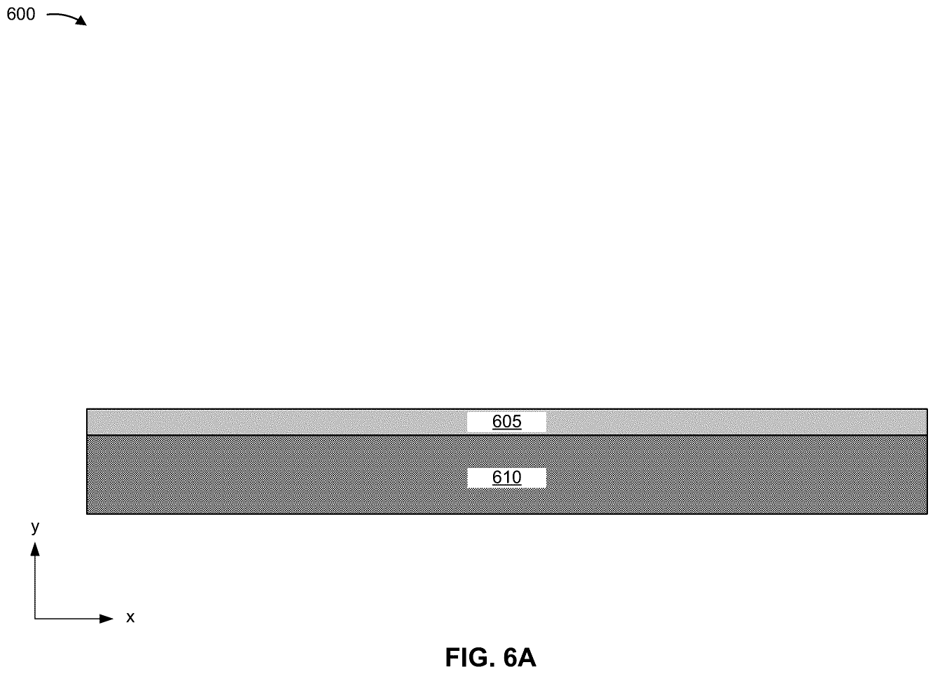

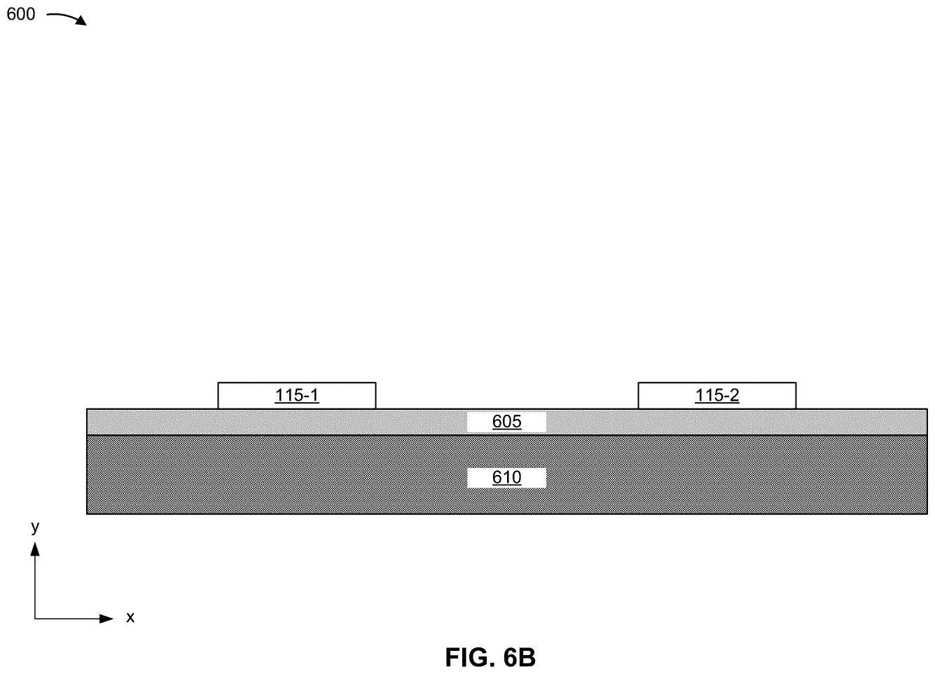

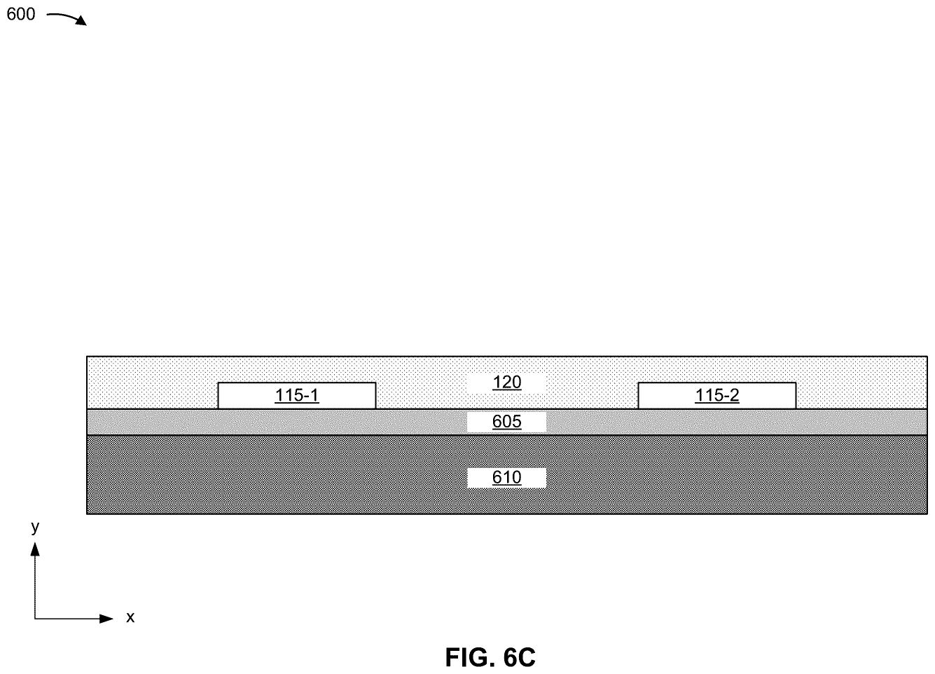

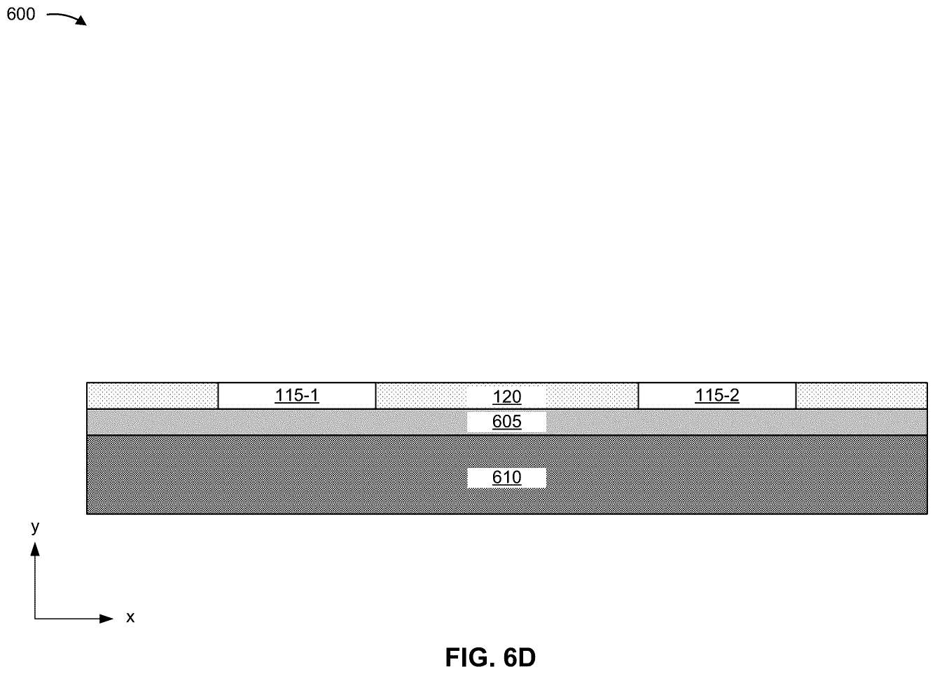

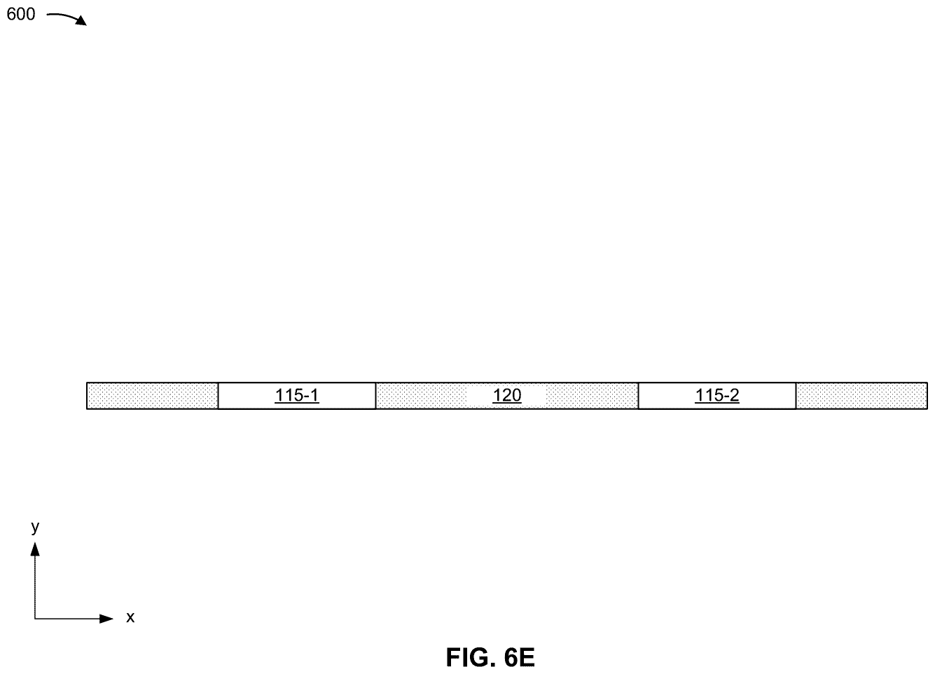

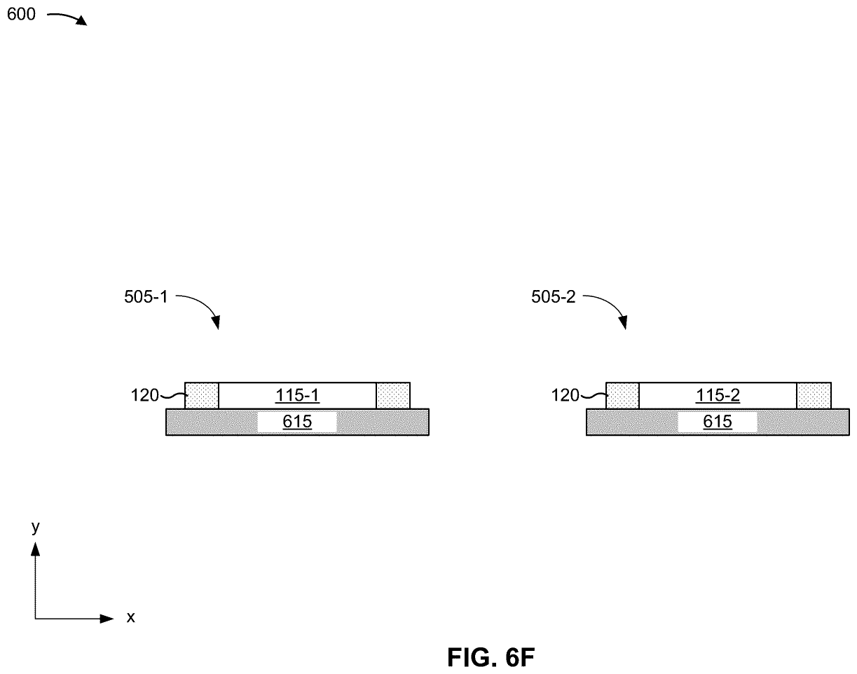

FIGS. 6A-6F are diagrams of an example implementation 600 for forming an example test vehicle for testing one or more properties related to an interfacial adhesion strength between an epoxy mold compound and a vertical edge of a die described herein. The implementation 600 may include a series of semiconductor processing operations that may be used to form the test vehicle 505, 510, and/or 515 as described in connection with FIG. 5.

As shown in FIG. 6A, the implementation 600 includes forming a release layer 605 (e.g., a temporary bonding layer) on a carrier 610 (a silicon carrier or a ceramic carrier, among other examples). As examples, forming the release layer may include using a coating technique or a spray coating technique to form the release layer 605 on the carrier 610.

Turning to FIG. 6B, the implementation 600 includes forming the dies 115-1 and 115-2 on the release layer 605. As an example, forming the dies 115-1 and 115-2 on the release layer may include using a die attach technique to place the dies 115-1 and 115-2 on the release layer 605.

Turning to FIG. 6C, the implementation 600 includes forming the casing 120 on and/or over the die 115-1, the die 115-2, and the release layer 605. As an example, forming the casing 120 may include using an injection molding and curing technique that uses an epoxy mold compound to form the casing 120.

Turning to FIG. 6D, the implementation 600 includes thinning the casing 120. As an example, thinning the casing may include using a back grind technique to thin the casing 120 to a same approximate thickness as the dies 115-1 and 115-2.

Turning to FIG. 6E, the implementation 600 includes releasing a subassembly including the die 115-1, the die 115-2, and the casing 120 from the carrier 610. As examples, releasing the die 115-1, the die 115-2, and the casing 120 from the carrier 610 may include using a chemical release technique, a thermal release technique, or a mechanical release technique.

Turning to FIG. 6F, the implementation 600 includes forming the interfacial adhesion test structures 505-1 and 505-2 on a dicing tape 615. As an example, forming the interfacial adhesion testing structures 505-1 and 505-2 on the dicing tape 615 may include using a die attach technique to place the subassembly of FIG. 6E on the dicing tape 615 and, using a dicing operation, separating the interfacial adhesion testing structures 505-1 and 505-2.

As indicated above, FIGS. 6A-6F are provided as an example. Other examples may differ from what is described with regard to FIGS. 6A-6F.

FIGS. 7A-7D are diagrams of example implementations of an interfacial adhesion strength testing tool 700 described herein. The interfacial adhesion strength testing tool 700 may include at least one actuator 705 and at least one controller 710. The actuator 705 (a motorized actuator or a hydraulic actuator, among other examples) may be instrumented with at least one gauge (a piezoelectric gauge or a strain gauge, among other examples) that is capable of determining a force generated by the actuator 705. The controller 710 (a processor or a combination of a processor and memory, among other examples) may communicate with, and/or monitor, the actuator 705 using one or more communication links 715. The one or more communication links 715 may include or more wireless-communication links, one or more wired-communication links, or a combination of one or more wireless-communication links and one or more wired-communication links, among other examples. In some implementations, the controller is separate from the interfacial adhesion strength testing tool 700. The interfacial adhesion strength testing tool 700 may further include at least one fixture 720 for supporting or holding a test vehicle (e.g., the test vehicle 305 described in connection with FIG. 3 and/or the test vehicles 505-515 described in connection with FIG. 5). The fixture 720 may be a simple support fixture or a clamp fixture, among other examples.

The interfacial adhesion strength testing tool 700 may determine one or more properties related to an interfacial strength within an interface region between an epoxy mold compound (e.g., an epoxy mold compound used in the casing 120) and vertical edges of a semiconductor die (e.g., the die 115). Such properties may correspond to an interfacial strain energy density, a bending stress, a tensile stress, or a shear stress at which failure occurs within the interface region.

As shown in the example implementation of FIG. 7A, a loading condition may correspond to a four point bend test loading condition. In FIG. 7A, the test vehicle 510 is supported by the fixtures 720-1 and 720-2 (e.g., simple support fixtures), where the fixtures 720-1 and 720-2 are separated by a distance L_{S}. Furthermore, and as shown in the implementation of FIG. 7A, the actuator 705-1 applies the mechanical load 325-1 to the test vehicle 510 and the actuator 705-2 applies the mechanical load 325-2 to the test vehicle 510, where the mechanical loads 325-1 and 325-2 are separated by distance LL.

In a symmetrical configuration, the mechanical load 325-1 and the mechanical load 325-2 may be approximately equivalent and contribute to a total load of W. Furthermore, and in the symmetrical loading condition, a distance a between a point of loading and a point of support may be determined using the following relationship:

$$a = ( {L}_{S} - {L}_{L} ) / 2$$

In the four-point bend test loading condition of FIG. 7A, the controller 710 may determine a magnitude of a loading condition at which an interfacial adhesion failure occurs to determine a bending stress σ (e.g., a normal stress due to bending in the casing 120 between the fixture 720-1 and the die 115) using the following relationship,

$$σ = 3 Wa / {bh}^{2}$$

where h is a thickness of the test vehicle 510 and b is a width of the test vehicle 510 (e.g., a depth of the test vehicle 510 into FIG. 7A).

As shown in the example implementation of FIG. 7B, a loading condition may correspond to a tensile test loading condition. Furthermore, and as shown in the implementation of FIG. 7B, the actuator 705-1 applies the mechanical load 325-1 to the test vehicle 510 and the actuator 705-2 applies the mechanical load 325-2 to the test vehicle 510, where the mechanical loads 325-1 and 325-2 are opposite to one another.

In the tensile test loading condition of FIG. 7B, the controller 710 may determine a magnitude of a loading condition at which an interfacial adhesion failure occurs within the test vehicle 510 to further determine a maximum interfacial tensile strength TMAX using the following relationship,

$${T}_{MAX} = {F}_{MAX} / {A}_{I}$$

where F_{MAX} is a loading at which the failure condition occurs, and where Ar is an area of a single interface region between the casing 120 and the die 115.

As shown in the example implementation of FIG. 7C, a loading condition may correspond to a shear test loading condition, where the test vehicle 515 is held by the fixture 720 (e.g., a clamp fixture). Furthermore, and as shown in the implementation of FIG. 7C, the actuator 705 applies the mechanical load 325 to the test vehicle 515.

In the shear test loading condition of FIG. 7C, and based on feedback received through the communication link 715, the controller 710 may determine a magnitude of a loading condition at which an interfacial adhesion failure occurs within the test vehicle 515 to further determine a maximum interfacial shear strength S_{MAX} using the following relationship:

$${S}_{MAX} = {F}_{MAX} / {A}_{I}$$

where F_{MAX} is a loading at which the failure condition occurs and where Ar is an area of an interface region between the casing 120 and the die 115.

As shown in the example implementation of FIG. 7D, a loading condition may correspond to a pure shear test loading condition (e.g., a punch test loading condition), where a perimeter of the test vehicle 505 is supported by the fixture 720 (a direct support fixture that supports a perimeter of the test vehicle 505). Furthermore, and as shown in the implementation of FIG. 7D, the actuator 705 applies the mechanical load 325 to the test vehicle 505.

In the pure shear test loading condition of FIG. 7D, and based on feedback received through the communication link 715, the controller 710 may determine a magnitude of a loading condition at which an interfacial adhesion failure occurs within the test vehicle 505 to further determine a maximum interfacial shear strength S_{MAX} using the following relationship:

$${S}_{MAX} = {F}_{MAX} / {A}_{I}$$

where F_{MAX} is a loading at which the failure condition occurs, and where A_{I} is an area of four interface regions between the casing 120 and the die 115.

In the implementations FIGS. 7A-7D, the controller 710 may determine or more properties related to an interfacial adhesion strength using finite element analysis (FEA) techniques. Additionally, or alternatively, the implementations of FIGS. 7A-7D may include different test environments (e.g., moisture and/or temperature conditions).

As described in connection with FIGS. 3, 5, and 7A-7D, an interfacial adhesion strength testing tool (e.g., the interfacial adhesion strength testing tool 700) may perform a series of operations. The series of operations includes monitoring a mechanical loading condition (e.g., the mechanical loads 325, 325-1, and/or 325-2) applied to an integrated assembly (e.g., the test vehicle 305, 505, 510, and/or 515) that includes a semiconductor die and an interfacial adhesion testing structure (e.g., one or more of the interfacial adhesion testing structures 310-1, 310-2, 310-3, 310-4, and/or 310-5) that extends laterally beyond a vertical edge of the semiconductor die, wherein the interfacial adhesion testing structure includes a same material (e.g., the epoxy moldy compound) as a casing structure (e.g., the casing 120) surrounding the semiconductor die; determining a magnitude of the mechanical loading condition at which an interfacial adhesion failure occurs within an interface region between the interfacial adhesion testing structure and the vertical edge of the semiconductor die; and determining one or more properties related to an interfacial strength within the interface region based on the magnitude of the mechanical loading condition.

As indicated above, FIGS. 7A-7D are provided as an example. Other examples may differ from what is described with regard to FIGS. 7A-7D. For example, the test vehicle 305 described in connection with FIG. 3, and/or the test vehicles 505-515 described in connection with FIG. 5, may each be used in connection with a described loading condition of FIGS. 7A-7D.

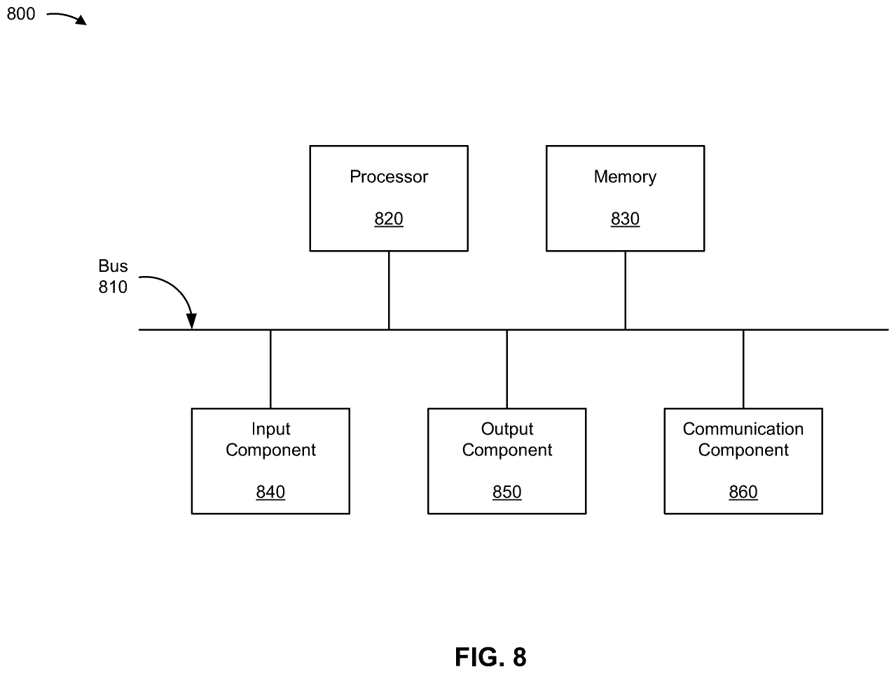

FIG. 8 is a diagram of example components of a device that characterizes properties related to an interfacial adhesion strength between an epoxy mold compound and vertical edges of a die described herein. The device 800 may correspond to the interfacial adhesion strength testing tool 700, the actuator 705, and/or the controller 710. In some implementations, interfacial adhesion strength testing tool 700, the actuator 705, and/or the controller 710 may include one or more devices 800 and/or one or more components of the device 800. As shown in FIG. 8, the device 800 may include a bus 810, a processor 820, a memory 830, an input component 840, an output component 850, and/or a communication component 860.

The bus 810 may include one or more components that enable wired and/or wireless communication among the components of the device 800. The bus 810 may couple together two or more components of FIG. 8, such as via operative coupling, communicative coupling, electronic coupling, and/or electric coupling. For example, the bus 810 may include an electrical connection (e.g., a wire, a trace, and/or a lead) and/or a wireless bus. The processor 820 may include a central processing unit, a graphics processing unit, a microprocessor, a controller, a microcontroller, a digital signal processor, a field-programmable gate array, an application-specific integrated circuit, and/or another type of processing component. The processor 820 may be implemented in hardware, firmware, or a combination of hardware and software. In some implementations, the processor 820 may include one or more processors capable of being programmed to perform one or more operations or processes described elsewhere herein.

The memory 830 may include volatile and/or nonvolatile memory. For example, the memory 830 may include random access memory (RAM), read only memory (ROM), a hard disk drive, and/or another type of memory (e.g., a flash memory, a magnetic memory, and/or an optical memory). The memory 830 may include internal memory (e.g., RAM, ROM, or a hard disk drive) and/or removable memory (e.g., removable via a universal serial bus connection). The memory 830 may be a non-transitory computer-readable medium. The memory 830 may store information, one or more instructions, and/or software (e.g., one or more software applications) related to the operation of the device 800. In some implementations, the memory 830 may include one or more memories that are coupled (e.g., communicatively coupled) to one or more processors (e.g., processor 820), such as via the bus 810. Communicative coupling between a processor 820 and a memory 830 may enable the processor 820 to read and/or process information stored in the memory 830 and/or to store information in the memory 830.

The input component 840 may enable the device 800 to receive input, such as user input and/or sensed input. For example, the input component 840 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 850 may enable the device 800 to provide output, such as via a display, a speaker, and/or a light-emitting diode. The communication component 860 may enable the device 800 to communicate with other devices via a wired connection and/or a wireless connection. For example, the communication component 860 may include a receiver, a transmitter, a transceiver, a modem, a network interface card, and/or an antenna.

The device 800 may perform one or more operations or processes described herein. For example, a non-transitory computer-readable medium (e.g., memory 830) may store a set of instructions (e.g., one or more instructions or code) for execution by the processor 820. The processor 820 may execute the set of instructions to perform one or more operations or processes described herein. In some implementations, execution of the set of instructions, by one or more processors 820, causes the one or more processors 820 and/or the device 800 to perform one or more operations or processes described herein. In some implementations, hardwired circuitry may be used instead of or in combination with the instructions to perform one or more operations or processes described herein. Additionally, or alternatively, the processor 820 may be configured to perform one or more operations or processes described herein. Thus, implementations described herein are not limited to any specific combination of hardware circuitry and software.

The number and arrangement of components shown in FIG. 8 are provided as an example. The device 800 may include additional components, fewer components, different components, or differently arranged components than those shown in FIG. 8. Additionally, or alternatively, a set of components (e.g., one or more components) of the device 800 may perform one or more functions described as being performed by another set of components of the device 800.

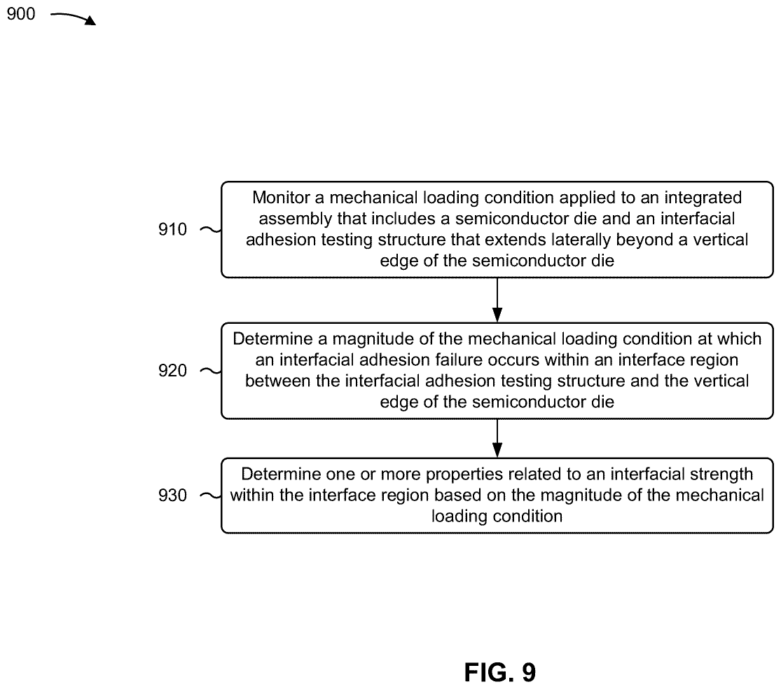

FIG. 9 is a flowchart of an example method 900 associated with testing properties related to an interfacial adhesion strength between an epoxy mold compound and vertical edges of a die. In some implementations, the interfacial adhesion strength testing tool 700 may perform or may be configured to perform the method 900. In some implementations, another device or a group of devices separate from or including the interfacial adhesion strength testing tool 700 (e.g., the actuator 705 and/or the controller 710) may perform or may be configured to perform the method 900. Additionally, or alternatively, one or more components of the interfacial adhesion strength testing tool 700 may perform or may be configured to perform the method 900. Thus, means for performing the method 900 may include the interfacial adhesion strength testing tool 700 and/or one or more components of the interfacial adhesion strength testing tool 700. Additionally, or alternatively, a non-transitory computer-readable medium may store one or more instructions that, when executed by the interfacial adhesion strength testing tool 700, cause the interfacial adhesion strength testing tool 700 to perform the method 900.

As shown in FIG. 9, the method 900 may include monitoring a mechanical loading condition applied to an integrated assembly that includes a semiconductor die and an interfacial adhesion testing structure that extends laterally beyond a vertical edge of the semiconductor die, wherein the interfacial adhesion testing structure includes a same material as a casing structure surrounding the semiconductor die (block 910). As further shown in FIG. 9, the method 900 may include determining a magnitude of the mechanical loading condition at which an interfacial adhesion failure occurs within an interface region between the interfacial adhesion testing structure and the vertical edge of the semiconductor die (block 920). As further shown in FIG. 9, the method 900 may include determining one or more properties related to an interfacial strength within the interface region based on the magnitude of the mechanical loading condition (block 930).

The method 900 may include additional aspects, such as any single aspect or any combination of aspects described below and/or described in connection with one or more other methods or operations described elsewhere herein.

In a first aspect, the mechanical loading condition corresponds to a pure shear test loading condition.

In a second aspect, alone or in combination with the first aspect, the mechanical loading condition corresponds to a tensile test loading condition.

In a third aspect, alone or in combination with one or more of the first and second aspects, the mechanical loading condition corresponds to a four-point bend test loading condition.

In a fourth aspect, alone or in combination with one or more of the first through third aspects, determining the one or more properties related to an interfacial strength comprises determining an interfacial tensile stress within the interfacial region at which the interfacial adhesion failure occurs.

In a fifth aspect, alone or in combination with one or more of the first through fourth aspects, determining the one or more properties related to an interfacial strength comprises determining an interfacial shear stress within the interfacial region at which the interfacial adhesion failure occurs.

In a sixth aspect, alone or in combination with one or more of the first through fifth aspects, determining the one or more properties related to an interfacial strength comprises determining an interfacial strain energy density within the interfacial region at which the interfacial adhesion failure occurs.

In a seventh aspect, alone or in combination with one or more of the first through sixth aspects, determining the interfacial strain energy density within the interfacial region at which the interfacial adhesion failure occurs comprises using finite element analysis modeling to determine the interfacial strain energy.

Although FIG. 9 shows example blocks of a method 900, in some implementations, the method 900 may include additional blocks, fewer blocks, different blocks, or differently arranged blocks than those depicted in FIG. 9. Additionally, or alternatively, two or more of the blocks of the method 900 may be performed in parallel. The method 900 is an example of one method that may be performed by one or more devices described herein. These one or more devices may perform or may be configured to perform one or more other methods based on operations described herein.

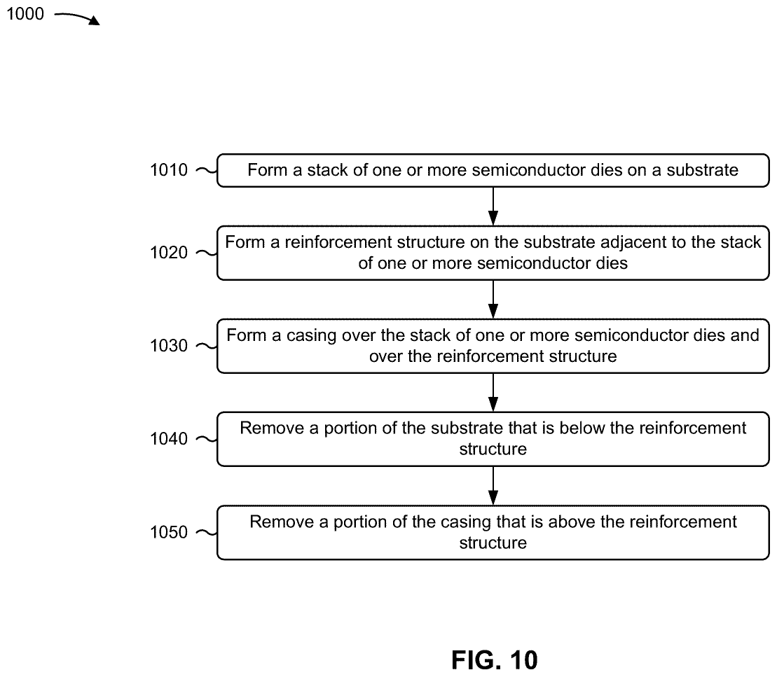

FIG. 10 is a flowchart of an example method 1000 of forming an integrated assembly having an interfacial adhesion testing structure (e.g., the interfacial adhesion testing structure 310). In some implementations, one or more process blocks of FIG. 10 may be performed by various semiconductor manufacturing equipment.

As shown in FIG. 10, the method 1000 may include forming a stack of one or more semiconductor dies on a substrate (block 1010). As further shown in FIG. 10, the method 1000 may include forming a reinforcement structure on the substrate adjacent to the stack of one or more semiconductor dies (block 1020). As further shown in FIG. 10, the method 1000 may include forming a casing over the stack of one or more semiconductor dies and over the reinforcement structure (block 1030). As further shown in FIG. 10, the method 1000 may include removing a portion of the substrate that is below the reinforcement structure (block 1040). As further shown in FIG. 10, the method 1000 may include removing a portion of the casing that is above the reinforcement structure, wherein removing the portion of the casing in combination with removing the portion of the substrate forms an interfacial adhesion testing structure that is reinforced and that extends laterally beyond vertical edges of the one or more semiconductor dies (block 1050).

The method 1000 may include additional aspects, such as any single aspect or any combination of aspects described below and/or in connection with one or more other methods described elsewhere herein.

In a first aspect, forming the reinforcement structure on the substrate adjacent to the stack of one or more semiconductor dies comprises using a die attach process to attach an approximately planar and rectangular structure on the substrate adjacent to the stack of one or more semiconductor dies.

In a second aspect, alone or in combination with the first aspect, the approximately planar and rectangular structure is a first approximately planar and rectangular structure, and forming reinforcement structure on the substrate adjacent to the stack of one or more semiconductor dies further comprises using the die attach process to attach a second approximately planar and rectangular structure onto a top surface of the first approximately planar and rectangular structure.

In a third aspect, alone or in combination with one or more of the first and second aspects, removing the portion of the substrate that is below the reinforcement structure comprises using a step cutting process to remove the portion.

In a fourth aspect, alone or in combination with one or more of the first through third aspects, removing the portion of the casing that is above the reinforcement structure comprises using a step cutting process to remove the portion.

In a fifth aspect, alone or in combination with one or more of the first through fourth aspects, forming the casing over the stack of one or more semiconductor dies and over the stack of one or more reinforcement structures comprises forming an epoxy mold compound over the stack of one or more semiconductor dies and over the reinforcement structure.

In a sixth aspect, alone or in combination with one or more of the first through fifth aspects, the method 1000 includes performing a pre-conditioning operation to pre-condition the epoxy mold compound prior to an interfacial adhesion strength test, wherein the pre-conditioning operation comprises a temperature and humidity cycling operation, a thermal aging operation, a high-temperature storage operation, a thermal shock operation, or a thermal cycling operation.

Although FIG. 10 shows example blocks of the method 1000, in some implementations, the method 1000 may include additional blocks, fewer blocks, different blocks, or differently arranged blocks than those depicted in FIG. 10. In some implementations, the method 1000 may include forming the interfacial adhesion testing structure 310, an integrated assembly that includes the interfacial adhesion testing structure 310, any part described herein of the interfacial adhesion testing structure 310, and/or any part described herein of an integrated assembly that includes the interfacial adhesion testing structure 310. For example, the method 1000 may include forming one or more of the reinforcement structures 315.

In some implementations, an integrated assembly includes a substrate; one or more semiconductor dies on the substrate; a casing having a first thickness over the one or more semiconductor dies and comprising an epoxy mold compound; and an interfacial adhesion testing structure extending laterally beyond vertical edges of the one or more semiconductor dies and beyond an edge of the substrate, wherein the interfacial adhesion testing structure comprises the epoxy mold compound, and wherein a second thickness of the interfacial adhesion testing structure is less than the first thickness.

In some implementations, an integrated assembly includes a semiconductor die; and an interfacial adhesion testing structure extending laterally beyond a vertical edge of the semiconductor die, wherein a thickness of the interfacial adhesion testing structure and a thickness of the semiconductor die are a same approximate thickness.

In some implementations, a method includes monitoring a mechanical loading condition applied to an integrated assembly that includes a semiconductor die and an interfacial adhesion testing structure that extends laterally beyond a vertical edge of the semiconductor die, wherein the interfacial adhesion testing structure includes a same material as a casing structure surrounding the semiconductor die; determining a magnitude of the mechanical loading condition at which an interfacial adhesion failure occurs within an interface region between the interfacial adhesion testing structure and the vertical edge of the semiconductor die; and determining one or more properties related to an interfacial strength within the interface region based on the magnitude of the mechanical loading condition.

In some implementations, a method includes forming a stack of one or more semiconductor dies on a substrate; forming a reinforcement structure on the substrate adjacent to the stack of one or more semiconductor dies; forming a casing over the stack of one or more semiconductor dies and over the reinforcement structure; removing a portion of the substrate that is below the reinforcement structure; and removing a portion of the casing that is above the reinforcement structure, wherein removing the portion of the casing in combination with removing the portion of the substrate forms an interfacial adhesion testing structure that is reinforced and that extends laterally beyond vertical edges of the one or more semiconductor dies.

As described in connection with FIGS. 3-10, an interfacial adhesion testing structure (e.g., the interfacial adhesion testing structure 310) may be used for characterizing properties related to an interfacial adhesion strength between an epoxy mold compound and vertical edges of a die (e.g., the die 115). Techniques using the interfacial adhesion testing structure may be used to provide a more comprehensive understanding of interfacial adhesion strengths within a semiconductor die package (e.g., the apparatus 100) relative to techniques described in semiconductor industry standards.

In this way, a thoroughness of a qualification of the semiconductor die package for field use may be improved, to reduce a rate of field failures and/or a rate of field returns for a market consuming the semiconductor die package. By reducing the rate of field failures and/or the rate of field returns, an amount of resources required to support the market consuming the semiconductor die package (e.g., semiconductor manufacturing tools, labor, raw materials, and/or computing resources) may be reduced.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for case of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a substrate;
one or more semiconductor dies on the substrate;
a casing having a first thickness over the one or more semiconductor dies and comprising an epoxy mold compound; and
an interfacial adhesion testing structure extending laterally beyond vertical edges of the one or more semiconductor dies and beyond an edge of the substrate,
wherein the interfacial adhesion testing structure comprises the epoxy mold compound, and
wherein a second thickness of the interfacial adhesion testing structure is less than the first thickness.

2. The integrated assembly of claim 1, wherein the interfacial adhesion testing structure comprises:
one or more reinforcement structures embedded in the epoxy mold compound.

3. The integrated assembly of claim 2, wherein the one or more reinforcement structures comprise:
at least two or more approximately planar and rectangular structures that are stacked in a vertical arrangement.

4. The integrated assembly of claim 3, wherein at least one of the two or more approximately planar and rectangular structures comprises:
a silicon material.

5. The integrated assembly of claim 3, wherein at least one of the two or more approximately planar and rectangular structures comprises:
a metal material,
a ceramic material, or
a composite material.

6. An integrated assembly, comprising:
a semiconductor die; and
an interfacial adhesion testing structure extending laterally beyond a vertical edge of the semiconductor die,
wherein a thickness of the interfacial adhesion testing structure and a thickness of the semiconductor die are a same approximate thickness.

7. The integrated assembly of claim 6, wherein the interfacial adhesion testing structure includes an epoxy mold compound.

8. The integrated assembly of claim 7, wherein the interfacial adhesion testing structure excludes a reinforcement structure.

9. The integrated assembly of claim 6, wherein in the interfacial adhesion testing structure is a first interfacial adhesion testing structure, the vertical edge is a first vertical edge, and wherein the integrated assembly further comprises:
a second interfacial adhesion testing structure extending laterally beyond a second vertical edge of the semiconductor die,
wherein the second vertical edge is an opposite edge of the semiconductor die that is approximately parallel to the first vertical edge, and
wherein a thickness of the second interfacial adhesion testing structure and the thickness of the semiconductor die are a same approximate thickness.

10. The integrated assembly of claim 6, wherein in the interfacial adhesion testing structure is a first interfacial adhesion testing structure, the vertical edge is a first vertical edge, and wherein the integrated assembly further comprises:
a second interfacial adhesion testing structure extending laterally beyond a second vertical edge of the semiconductor die that intersects the first vertical edge,
wherein the second vertical edge is an adjacent edge of the semiconductor die that is approximately orthogonal to the first vertical edge, and
wherein a thickness of the second interfacial adhesion testing structure and the thickness of the semiconductor die are a same approximate thickness.

11. A method, comprising:
monitoring a mechanical loading condition applied to an integrated assembly that includes a semiconductor die and an interfacial adhesion testing structure that extends laterally beyond a vertical edge of the semiconductor die,
wherein the interfacial adhesion testing structure includes a same material as a casing structure surrounding the semiconductor die;
determining a magnitude of the mechanical loading condition at which an interfacial adhesion failure occurs within an interface region between the interfacial adhesion testing structure and the vertical edge of the semiconductor die; and
determining one or more properties related to an interfacial strength within the interface region based on the magnitude of the mechanical loading condition.

12. The method of claim 11, wherein the mechanical loading condition corresponds to a pure shear test loading condition.

13. The method of claim 11, wherein the mechanical loading condition corresponds to a tensile test loading condition.

14. The method of claim 11, wherein the mechanical loading condition corresponds to a four point bend test loading condition.

15. The method of claim 11, wherein determining the one or more properties related to an interfacial strength comprises:
determining an interfacial tensile stress within the interfacial region at which the interfacial adhesion failure occurs.

16. The method of claim 11, wherein determining the one or more properties related to an interfacial strength comprises:
determining an interfacial shear stress within the interfacial region at which the interfacial adhesion failure occurs.

17. The method of claim 11, wherein determining the one or more properties related to an interfacial strength comprises:
determining an interfacial strain energy density within the interfacial region at which the interfacial adhesion failure occurs.

18. The method of claim 17, wherein determining the interfacial strain energy density within the interfacial region at which the interfacial adhesion failure occurs comprises:
using finite element analysis modeling to determine the interfacial strain energy.

19. A method, comprising:
forming a stack of one or more semiconductor dies on a substrate;
forming a reinforcement structure on the substrate adjacent to the stack of one or more semiconductor dies;
forming a casing over the stack of one or more semiconductor dies and over the reinforcement structure;
removing a portion of the substrate that is below the reinforcement structure; and
removing a portion of the casing that is above the reinforcement structure,
wherein removing the portion of the casing in combination with removing the portion of the substrate forms an interfacial adhesion testing structure that is reinforced and that extends laterally beyond vertical edges of the one or more semiconductor dies.

20. The method of claim 19, wherein forming the reinforcement structure on the substrate adjacent to the stack of one or more semiconductor dies comprises:
using a die attach process to attach an approximately planar and rectangular structure on the substrate adjacent to the stack of one or more semiconductor dies.

21. The method of claim 20, wherein the approximately planar and rectangular structure is a first approximately planar and rectangular structure, and wherein forming reinforcement structure on the substrate adjacent to the stack of one or more semiconductor dies further comprises:
using the die attach process to attach a second approximately planar and rectangular structure onto a top surface of the first approximately planar and rectangular structure.

22. The method of claim 19, wherein removing the portion of the substrate that is below the reinforcement structure comprises:
using a step cutting process to remove the portion.

23. The method of claim 19, wherein removing the portion of the casing that is above the reinforcement structure comprises:
using a step cutting process to remove the portion.

24. The method of claim 19, wherein forming the casing over the stack of one or more semiconductor dies and over the stack of one or more reinforcement structures comprises:
forming an epoxy mold compound over the stack of one or more semiconductor dies and over the reinforcement structure.

25. The method of claim 24, further comprising performing a pre-conditioning operation to pre-condition the epoxy mold compound prior to an interfacial adhesion strength test, wherein the pre-conditioning operation comprises:
a temperature and humidity cycling operation,
a thermal aging operation,
a high-temperature storage operation,
a thermal shock operation, or
a thermal cycling operation.
